(19) United States
(12) Patent Application Publication
(10) Pub. No.: US 2025/0054779 A1
(43) Pub. Date: Feb. 13, 2025

(54) SEMICONDUCTOR PROCESSING DEVICE AND EXHAUST SYSTEM THEREOF

(71) Applicant: BEIJING NAURA MICROELECTRONICS EQUIPMENT CO., LTD., Beijing (CN)

(72) Inventors: Lika WANG, Beijing (CN); Lei SHI, Beijing (CN)

(21) Appl. No.: 18/722,085

(22) PCT Filed: Dec. 8, 2022
(86) PCT No.: PCT/CN2022/137450

§ 371 Date: Jun. 20, 2024

(30) Foreign Application Priority Data
Dec. 22, 2021 (CN) 202111581437.5

(51) Int. Cl. H01L 21/67

(52) U.S. Cl. CPC H01L 21/67017; H01L 21/67253

(57) ABSTRACT

An exhaust system connected to a process chamber in a semiconductor processing device includes: a switching device; a first pressure control mechanism; and a second pressure control mechanism. The switching device is connected to the process chamber, and is connected to the first pressure control mechanism and the second pressure control mechanism for switching between the first pressure control mechanism and the second pressure control mechanism to discharge the gases and control the pressure in the process chamber. The first pressure control mechanism includes a first pressure control pipeline and a first controller, and the first pressure control pipeline is connected to the switching device and is used to discharge the gases in the process chamber. The first controller is disposed at the first pressure control pipeline to control the process chamber to maintain a first pressure when the first pressure control pipeline discharges the gases.

### TECHNICAL FIELD

The present disclosure generally relates to the field of semiconductor processing technology and, more particularly, to a semiconductor processing device and an exhaust system thereof.

### BACKGROUND

Currently, in a semiconductor processing device, a wafer is subject to process reactions in a process chamber. To ensure that the process reactions on the wafer are uniform and controllable, a stable pressure needs to be provided in the process chamber. In semiconductor processing practices, a pressure control device is often added to an exhaust system of the process chamber to obtain the stable pressure. With the development of semiconductor processing technology, two pressure control modes having a normal pressure (absolute pressure 758-760 Torr) and a low pressure (absolute pressure 50 Torr), are often required in different steps of a process to achieve different process results in an existing advanced process. However, the exhaust system in the prior art can only achieve the normal pressure (absolute pressure 758-760 Torr) or a micro-low pressure (absolute pressure 680-750 Torr), but cannot achieve the low pressure (absolute pressure 50 Torr) pressure. In addition, the existing exhaust system has only a capability of achieving a single micro-low pressure, but cannot simultaneously achieve the micro-low pressure and the normal pressure, thereby substantially reducing a process rate.

### SUMMARY

In view of the shortcomings of the existing methods, the present disclosure provides a semiconductor processing device and an exhaust system thereof to solve the technical problems of the prior art that the low-pressure control cannot be achieved and that various different pressure control requirements cannot be met.

The present disclosure also provides an exhaust system connected to a process chamber in a semiconductor processing device to discharge gases and control a pressure in the process chamber. The exhaust system includes: a switching device; a first pressure control mechanism; and a second pressure control mechanism. The switching device is connected to the process chamber, and is connected to the first pressure control mechanism and the second pressure control mechanism for switching between the first pressure control mechanism and the second pressure control mechanism to discharge the gases and control the pressure in the process chamber. The first pressure control mechanism includes a first pressure control pipeline and a first controller, and the first pressure control pipeline is connected to the switching device and is used to discharge the gases in the process chamber; the first controller is disposed at the first pressure control pipeline to control the process chamber to maintain a first pressure when the first pressure control pipeline discharges the gases. The second pressure control mechanism includes a second pressure control pipeline and a second controller, and the second pressure control pipeline is connected to the switching device and is used to discharge the gases in the process chamber; the second controller is disposed at the second pressure control pipeline to control the process chamber to maintain a second pressure when the second pressure control pipeline discharges the gases; and the second pressure is greater than the first pressure.

In some embodiments, the first pressure control mechanism further includes an exhaust device, the exhaust device is connected to the first pressure control pipeline, and the first controller is used to control the exhaust device to discharge the gases in the process chamber.

In some embodiments, the first pressure control pipeline includes a first exhaust pipe and a variable diameter exhaust pipe, one end of the first exhaust pipe is connected to the switching device, and the other end of the first exhaust pipe is connected to one end of the variable diameter exhaust pipe. The other end of the variable diameter exhaust pipe is connected to the exhaust device. The first controller is arranged at one of the first exhaust pipe and the variable diameter exhaust pipe, or at a connection between the first exhaust pipe and the variable diameter exhaust pipe.

In some embodiments, the first pressure control mechanism further includes a detection component, which is disposed at the first exhaust pipe and is used to detect a pressure signal in the first exhaust pipe, and the first controller is used to control the pressure in the process chamber according to the pressure signal.

In some embodiments, the detection component includes a first detection component and a second detection component, the first detection component and the second detection component are arranged at the first exhaust pipe, the second detection component is located on a side of the first detection component facing away from the switching device, and the first detection component has a detection range greater than a detection range of the second detection component.

In some embodiments, the first pressure control mechanism further includes a pressure differential detection component, two ends of the pressure differential detection component are respectively connected to the first pressure control pipeline and the second pressure control pipeline, for detecting a pressure difference signal between the two. When the pressure difference signal reaches a first threshold, the switching device switches from discharging through the first pressure control pipeline to discharging through the second pressure control pipeline, and the first controller is turned off.

In some embodiments, the switching device includes a main body and a piston, the main body includes an air inlet, a first air outlet, and a second air outlet, the air inlet is connected to an exhaust port of the process chamber, the first air outlet is connected to the first pressure control pipeline, and the second air outlet is connected to the second pressure control pipeline. At least a portion of the piston is slidably arranged in the main body, the piston slides back and forth in the main body, and is used to selectively connect the air inlet with the first air outlet or with the first air outlet and the second air outlet.

In some embodiments, the main body includes a gas channel and a sliding channel, one end of the gas channel is the first gas outlet, the other end of the gas channel is connected to one end of the sliding channel, and the gas inlet is connected to the gas channel. The second gas outlet is connected to the sliding channel, the piston includes a sliding portion, the sliding portion is slidably arranged in the sliding channel, and one of an end surface of the sliding portion facing toward the gas channel and an end surface of the sliding channel facing toward the sliding portion includes a first sealing member, and the sliding portion slides to a position where it is sealed and connected to an end surface of the sliding channel through the first sealing member to disconnect the gas channel and the sliding channel.

In some embodiments, the switching device further includes an end cover arranged on the main body, the end cover is located at the other end of the sliding channel facing away from the gas channel, the end cover is sealed and connected to the main body through a second seal to seal the sliding channel. A sliding hole is provided on the end cover, the piston further includes a sliding rod integrally arranged with the sliding portion, the sliding rod is penetrated in the sliding hole and slides with the sliding hole, a third seal is provided on one of an inner peripheral wall of the sliding hole and an outer peripheral wall of the sliding rod, and the inner peripheral wall of the sliding hole and the outer peripheral wall of the sliding rod are sealed by the third seal.

In some embodiments, the switching device further includes a driving member arranged on a side of the end cover facing away from the main body, and the driving member is connected to the sliding rod, and is used to drive the sliding portion to reciprocate through the sliding rod.

In some embodiments, the second pressure control mechanism includes a condensation pipeline component, one end of the condensation pipeline component is connected to the second gas outlet, the other end is connected to the second pressure control pipeline, and the condensation pipeline component is used to condense and recover water vapor in the discharged gases.

In some embodiments, the condensation pipeline component includes a bellows, a damping tube, a condenser, a water-gas separator, and a water reservoir, two ends of the bellows are respectively connected to the second air outlet and one end of the damping tube, the other end of the damping tube is connected to an inlet of the water-gas separator, the condenser is covered outside the damping tube, the second pressure control pipeline is connected to an outlet of the water-gas separator, and the water reservoir is connected to a water outlet of the water-gas separator.

In some embodiments, the second pressure control mechanism further includes a pressure detection tube, one end of the pressure detection tube is connected to the water-gas separator, the other end is connected to the second controller for detecting the pressure signal in the process chamber, and the second controller is used to control the pressure in the process chamber according to the pressure signal.

Another aspect of the present disclosure provides a semiconductor processing device. The semiconductor device includes the process chamber and the disclosed exhaust system.

The present disclosure includes the following beneficial effects.

The embodiments of the present disclosure include two pressure control mechanisms, and switch between the first pressure control mechanism and the second pressure control mechanism through a switching device to control the pressure in the process chamber, such that the process chamber can be selectively maintained at the first pressure or the second pressure. That is, the embodiments of the present disclosure control the process chamber to be maintained at one of two different pressures, such as maintaining the pressure in the process chamber at the normal pressure (absolute pressure 758-760 Torr) or the low pressure (absolute pressure 50 Torr), which not only substantially expands the scope of application, but also substantially improves the process rate because the switching device can quickly switch between two pressure control mechanisms.

Additional aspects and advantages of the present disclosure will be partially given in the following description, which will become obvious from the following description or be understood through the practice of the present disclosure.

### BRIEF DESCRIPTION OF THE DRAWINGS

The above and/or additional aspects and advantages of the present disclosure will become apparent and easy to understand from the following description of the embodiments in conjunction with the accompanying drawings.

FIG. 1 is a schematic structural diagram of an exhaust system being coupled with a process chamber according to some embodiments of the present disclosure; and

FIG. 2 is a cross-sectional view of a switching device according to some embodiments of the present disclosure.

### DETAILED DESCRIPTION OF THE EMBODIMENTS

The present disclosure is described in detail below, and examples of embodiments of the present disclosure are shown in the accompanying drawings. Same or similar reference numerals throughout represent same or similar components or components with same or similar functions. In addition, if a detailed description of a known technology is unnecessary for the features of the present disclosure shown, it will be omitted. The embodiments described below with reference to the accompanying drawings are merely exemplary and are used to explain the present disclosure, and should not be interpreted as limiting the present disclosure.

It should be understood by those skilled in the art that, unless otherwise defined, all terms (including technical and scientific terms) used herein have the same meaning as the general understanding of ordinary technicians in the field to which the present disclosure belongs. It should also be understood that terms such as those defined in general dictionaries should be understood to have a meaning consistent with the meaning in the context of the prior art, and will not be interpreted with an idealized or overly formal meaning unless specifically defined as herein.

The technical solution of the present disclosure and how the technical solution of the present disclosure solves the above technical problems are described in detail below with various embodiments.

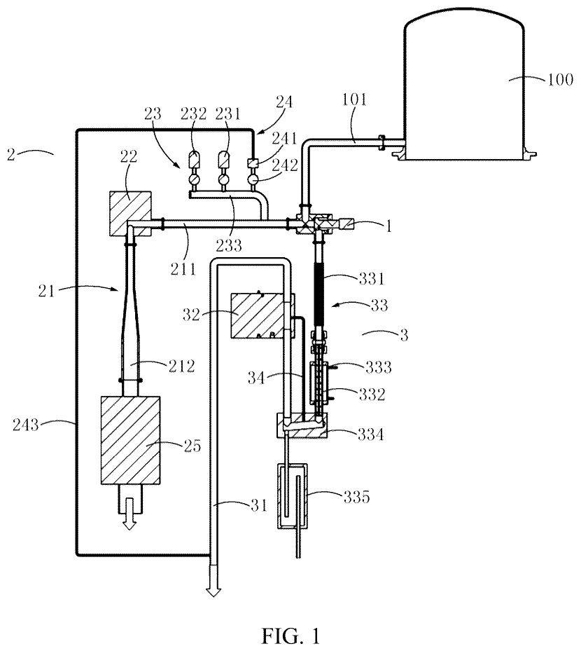

The present disclosure provides an exhaust system in a semiconductor processing device. The exhaust system is connected to a process chamber of the semiconductor processing device and is used to discharge gases in the process chamber and to control a pressure in the process chamber. FIG. 1 is a schematic structural diagram of an exhaust system being coupled with a process chamber according to some embodiments of the present disclosure. As shown in FIG. 1, the exhaust system includes: a switching device 1, a first pressure control mechanism 2, and a second pressure control mechanism 3.

The switching device 1 is connected to the process chamber 100, and is connected to the first pressure control mechanism 2 and the second pressure control mechanism 3. The switching device 1 is used to switch between the first pressure control mechanism 2 and the second pressure control mechanism 3 to control the pressure and discharge the gases in the process chamber 100.

The first pressure control mechanism 2 includes a first pressure control pipeline 21 and a first controller 22. The first pressure control pipeline 21 is connected to the switching device 1, and is used to discharge the gases in the process chamber 100. The first controller 22 is disposed at the first pressure control pipeline 21 to control the process chamber 100 to maintain a first pressure when the first pressure control pipeline 21 discharges the gases.

The second pressure control mechanism 3 includes a second pressure control pipeline 31 and a second controller 32. The second pressure control pipeline 31 is connected to the switching device 1, and is used to discharges the gases in the process chamber 100. The second controller 32 is disposed at the second pressure control pipeline 31 to control the process chamber 100 to maintain a second pressure when the second pressure control pipeline 31 discharges the gases. The second pressure is greater than the first pressure.

As shown in FIG. 1, the semiconductor processing device may be a heat treatment device for performing a heat treatment process on a wafer, but the embodiments of the present disclosure are not limited thereto. Those skilled in the art may adjust the configurations according to actual conditions. The wafer is placed in the process chamber 100. Process gases are injected into the process chamber 100 to perform the above process. The exhaust system is connected to the process chamber 100, and is used to control the pressure in the process chamber 100 while discharging the gases in the process chamber 100. The switching device 1 may be connected to an exhaust transition pipe 101 of the process chamber 100, or the switching device 1 may be directly connected to the process chamber 100. The first pressure control mechanism 2 and the second pressure control mechanism 3 are both connected to the switching device 1, and the switching device 1 may be used to switch between the first pressure control mechanism 2 and the second pressure control mechanism 3 to control the pressure in the process chamber 100. The first pressure control mechanism 2 may include the first pressure control pipeline 21 and the first controller 22. The first pressure control pipeline 21 may be connected to the switching device 1, and is used to discharge the gases in the process chamber 100. The first controller 22 may be an automatic control valve, which is disposed at the first pressure control pipeline 21 to control the process chamber 100 to maintain the first pressure when the first pressure control pipeline 21 discharges the gases. The first pressure may be, for example, the low pressure (absolute pressure 50 Torr). The second pressure control mechanism 3 may include the second pressure control pipeline 31 and the second controller 32. The second pressure control pipeline 31 is connected to the switching device 1, and is used to discharge the gases in the process chamber 100. The second controller 32 may be an automatic control valve, which is disposed at the second pressure control pipeline 31 to control the process chamber 100 to maintain the second pressure when the second pressure control pipeline 31 discharges the gases. The second pressure may be, for example, the normal pressure (absolute pressure 758-760 Torr) or the micro-low pressure (absolute pressure of 680-750 Torr). That is, the second pressure is greater than the first pressure. In actual applications, the exhaust system may be connected to a lower computer of the semiconductor processing device. When performing different process steps, an exhaust pressure may be controlled by switching to the corresponding pressure control mechanism through the switching device 1, to achieve the purpose of being compatible with two different pressure controls at the same time, thereby substantially improving process efficiency and economic benefits.

In some embodiments, two pressure control mechanisms are used to switch between the first pressure control mechanism and the second pressure control mechanism through the switching device to control the pressure in the process chamber, such that the first pressure or the second pressure can be maintained in the process chamber. In some embodiments, the process chamber is selectively controlled to maintain one of two different pressure states, for example, maintaining the normal pressure (absolute pressure 758-760 Torr) or the low pressure (absolute pressure 50 Torr). The present disclosure not only substantially expands an application scope of the embodiments of the present disclosure to improve applicability and scope of the embodiments of the present disclosure, but also quickly switches between the two pressure control mechanisms through the switching device to substantially improve the process rate.

It should be noted that the embodiments of the present disclosure do not limit the number of pressure control mechanisms included in the exhaust system, and the exhaust system may include more than two pressure control mechanisms. A pressure control range corresponding to each pressure control mechanism is not limited. For example, the pressure control range corresponding to the first pressure control mechanism 2 and the second pressure control mechanism 3 may be interchangeable. Thus, the embodiments of the present disclosure are not limited thereto, and those skilled in the art may adjust the configuration according to actual conditions.

In some embodiments, as shown in FIG. 1, the first pressure control mechanism 2 further includes an exhaust device 25. The exhaust device 25 is connected to the first pressure control pipeline 21. The first controller 22 is used to control the exhaust device 25 to discharge the gases in the process chamber 100. For example, the exhaust device 25 may be a vacuum pump, may be connected to the first pressure control pipeline 21, and may be a low-pressure power source to extract the gases in the process chamber 100. The exhaust device 25 may also be connected to a factory/building exhaust pipeline to discharge the gases in the process chamber 100 to the factory exhaust pipeline. In some embodiments, the first controller 22 may be electrically connected to the exhaust device 25 to control an operation state of the exhaust device 25 according to demand. But the embodiments of the present disclosure are not limited thereto. For example, the exhaust device 25 may be directly connected to the lower computer of the semiconductor processing device, and the lower computer controls the operation state of the exhaust device 25. With the above design, the exhaust device 25 facilitates the process chamber 100 to quickly reach the first pressure, thereby substantially improving the process rate.

It should be noted that the embodiments of the present disclosure do not limit a type of the air extraction device 25, as long as it provides the low-pressure power source for the first pressure control pipeline 21. Thus, the embodiments of the present disclosure are not limited thereto, and those skilled in the art can adjust the configuration according to actual conditions.

In some embodiments, as shown in FIG. 1, the first pressure control pipeline 21 includes a first exhaust pipe 211 and a variable diameter exhaust pipe 212. One end of the first exhaust pipe 211 is connected to the switching device 1, the other end of the first exhaust pipe 211 is connected to one end of the variable diameter exhaust pipe 212, and the other end of the variable diameter exhaust pipe 212 is connected to the exhaust device 25. The first controller 22 is arranged at one of the first exhaust pipe 211 and the variable diameter exhaust pipe 212, or at a connection between the first exhaust pipe 211 and the variable diameter exhaust pipe 212. For example, as shown in FIG. 1, the first controller 22 is arranged at the connection between the first exhaust pipe 211 and the variable diameter exhaust pipe 212. For example, the first controller 22 is arranged at the connection between the first exhaust pipe 211 and the variable diameter exhaust pipe 212, and the first controller 22 includes a body and a connecting channel arranged in the body. One end of the first exhaust pipe 211 is connected to the switching device 1, and the other end is connected to one end of the connecting channel of the body of the first controller 22. The variable diameter exhaust pipe 212 may be a tubular structure, and diameters at both ends thereof are different. A middle part of the variable diameter exhaust pipe 212 is a gradual structure with gradually changing diameters. An end with a relatively small diameter of the variable diameter exhaust pipe 212 is connected to the other end of the connecting channel of the body of the first controller 22, and another end with a relatively large diameter of the variable diameter exhaust pipe 212 is connected to the exhaust device 25. Because the variable diameter exhaust pipe 212 is used to match a diameter of an air inlet of the exhaust device 25 with a diameter of the first exhaust pipe 211, the above design not only has a simple and easy to use structure, but also avoids losing a discharging force of the exhaust device 25, thereby improving an operation efficiency.

It should be noted that the embodiments of the present disclosure do not limit the specific structure of the first pressure control pipeline 21. For example, the first exhaust pipe 211 and the variable diameter exhaust pipe 212 may be an integrated structure. Thus, the embodiments of the present disclosure are not limited thereto, and those skilled in the art may adjust the configuration according to actual conditions.

In some embodiments, as shown in FIG. 1, the first pressure control mechanism 2 further includes a detection component 23, which is disposed at the first exhaust pipe 211 and is used to detect a pressure signal in the first exhaust pipe 211. The first controller 22 is used to control the pressure in the process chamber 100 according to the pressure signal. Further, the detection component 23 may be disposed at the first exhaust pipe 211 and disposed close to the switching device 1 to detect the pressure signal in the first exhaust pipe 211, thereby detecting the pressure signal in the process chamber 100. The detection component 23 is electrically connected to the first controller 22, and the pressure signal may be sent to the first controller 22. The first controller 22 may control the pressure in the process chamber 100 according to the pressure signal. In actual applications, the detection component 23 may detect the pressure signal of the first exhaust pipe 211, and may transmit the pressure signal to the first controller 22 for automatic pressure control, thereby ensuring that the pressure in the process chamber 100 is accurately controlled at the first pressure. The above design can not only accurately control the pressure in the process chamber 100, but also automates a pressure control of the process chamber 100, thereby substantially improving process yield and operation efficiency.

It should be noted that the embodiments of the present disclosure do not limit the specific type of the detection component 23, as long as it can detect the pressure in the first exhaust pipe 211. Thus, the embodiments of the present disclosure are not limited thereto, and those skilled in the art may adjust the configuration according to actual conditions.

In some embodiments, as shown in FIG. 1, the detection component 23 includes a first detection component 231 and a second detection component 232. The first detection component 231 and the second detection component 232 are arranged at the first exhaust pipe 211, and the second detection component 232 is located on a side of the first detection component 231 facing away from the switching device 1. The first detection component 231 has a detection range greater than a detection range of the second detection component 232. In some embodiments, the detection range of the first detection component 231 is approximately between 0 Torr and 1000 Torr, and the detection range of the second detection component 232 is approximately between 0 Torr and 100 Torr.

As shown in FIG. 1, the first detection component 231 includes a first sensor and a first valve. The first sensor may be a vacuum gauge, and may have a detection range approximately between 0 Torr and 1000 Torr. The first sensor is disposed at the first exhaust pipe 211 through a first connecting pipe. The first valve may be a pneumatic valve, and may be disposed at the first connecting pipe. The first valve is used to open or close the first connecting pipe such that the first sensor either detects the pressure in the first exhaust pipe 211 or stops detecting. The second detection component 232 includes a second sensor and a second valve. The second sensor may be a vacuum gauge, and may have a detection range approximately between 0 Torr and 100 Torr. The second sensor is disposed on the first exhaust pipe 211 through a second connecting pipe. The second valve may be a pneumatic valve, and may be disposed at the second connecting pipe. The second valve is used to open or close the second connecting pipe such that the second sensor either detects the pressure in the first exhaust pipe 211 or stops detecting. In the above design, when the pressure in the process chamber 100 is relatively high, only the first detection component 231 may be used for detection, and the second valve may be turned off to prevent the second detection component 232 from being damaged by excessive pressure, thereby improving safety and reducing operation and maintenance costs. When the process chamber 100 is close to the first pressure, that is, close to 50 Torr, only the second detection component 232 may be used for detection. Because the second detection component 232 has a relatively small detection range, a detection accuracy thereof may be improved, thereby further improving an accuracy of the pressure control. In some embodiments, the detection component 23 also includes a supporting tube 233, which adopts, for example, an “L”-shaped structure. One end of the supporting tube 233 is connected to the first exhaust pipe 211, and the other end is closed. In some embodiments, two mutually perpendicular pipe sections of the “L”-shaped supporting tube 233 have different lengths. A first pipe section away from the first exhaust pipe 211 has a length greater than a length of a second pipe section adjacent to the first exhaust pipe 211, such that sufficient space is available on the first pipe section away from the first exhaust pipe 211 for connecting the first detection component 231 and the second detection component 232, as well as other components. The first detection component 231 and the second detection component 232 are both arranged on the supporting tube 233. That is, the first detection component 231 and the second detection component 232 are arranged on the first exhaust pipe 211 through the supporting tube 233. The above design may prevent particles and impurities in the first exhaust pipe 211 from entering the first detection component 231 and the second detection component 232 to cause any damage, thereby substantially reducing the failure rate and thus substantially extending the service life.

It should be noted that the embodiments of the present disclosure do not limit the detection ranges of the first detection component 231 and the second detection component 232, and the ranges thereof may be configured corresponding to actual pressure control requirements of the process chamber 100. Thus, the embodiments of the present disclosure are not limited thereto, and those skilled in the art may adjust the configuration according to actual conditions.

In some embodiments, as shown in FIG. 1, the first pressure control mechanism 2 further includes a pressure differential detection component 24. Two ends of the pressure differential detection component 24 are respectively connected to the first pressure control pipeline 21 and the second pressure control pipeline 31, for detecting a pressure difference signal between the two. When the pressure difference signal reaches a first threshold, the switching device 1 switches from discharging through the first pressure control pipeline 21 to discharging through the second pressure control pipeline 31, and the first controller 22 is turned off.

As shown in FIG. 1, the pressure differential detection component 24 includes a differential pressure gauge 241, a differential pressure valve 242, and a differential pressure pipe 243. The differential pressure gauge 241 is connected to the first exhaust pipe 211 through a third connecting pipe. For example, the differential pressure gauge 241 is connected to the supporting tube 233 through the third connecting pipe, thereby connecting between the differential pressure gauge 241 and the first exhaust pipe 211. The differential pressure valve 242 is arranged on the third connecting pipe for opening or closing the third connecting pipe. One end of the differential pressure pipe 243 is connected to the differential pressure gauge 241, and the other end is connected to the second pressure control pipeline 31. When the process chamber 100 needs to switch from the first pressure to the second pressure, the differential pressure valve 242 opens the third connecting pipe such that the differential pressure gauge 241 can detect a pressure difference between the first exhaust pipe 211 and the second pressure control pipeline 31. When the pressure difference reaches a second threshold, the switching device 1 may switch the first pressure control pipeline 21 to the second pressure control pipeline 31 to control the exhaust pressure through the second pressure control pipeline 31. It should be noted that the embodiments of the present disclosure do not limit a numerical range of the second threshold, and those skilled in the art may adjust the configuration according to actual conditions. In the above design, due to the provision of the differential pressure detection component 24, the pressures of the first pressure control pipeline 21 and the second pressure control pipeline 31 are compared to avoid damages to the second controller 32 due to excessive pressure fluctuations, thereby further reducing the failure rate and extending the service life.

It should be noted that the embodiments of the present disclosure do not limit the provision of the pressure differential detection component 24. For example, the pressure of the process chamber 100 may be directly detected and compared with the second pressure control pipeline 31. Thus, the embodiments of the present disclosure are not limited thereto, and those skilled in the art may adjust the configuration according to actual conditions.

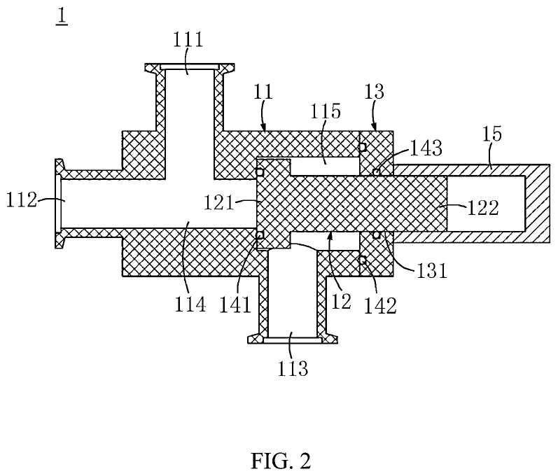

In some embodiments, as shown in FIG. 1 and FIG. 2, the switching device 1 includes a main body 11 and a piston 12. The main body 11 includes an air inlet 111, a first air outlet 112, and a second air outlet 113. The air inlet 111 is connected to an exhaust port of the process chamber 100. The first air outlet 112 is connected to the first pressure control pipeline 21, and the second air outlet 113 is connected to the second pressure control pipeline 31. At least a portion of the piston 12 is slidably arranged in the main body 11. The piston 12 slides back and forth in the main body 11, and is used to selectively connect the air inlet 111 with the first air outlet 112 or with the first air outlet 112 and the second air outlet 113.

As shown in FIG. 1 and FIG. 2, the main body 11 may be, for example, a block structure made of metallic material. However, the embodiments of the present disclosure do not limit the material of the main body 11, as long as it is corrosion resistant. The main body 11 includes the air inlet 111, the first air outlet 112, and the second air outlet 113. The air inlet 111 is connected to the exhaust transition pipe 101 of the process chamber 100. The first air outlet 112 is connected to the first exhaust pipe 211 of the first pressure control pipeline 21. That is, the first air outlet 112 is connected to the first pressure control pipeline 21. The second air outlet 113 is connected to the second pressure control pipeline 31. The piston 12 may be slidably arranged in the main body 11, and is controlled to reciprocate in the main body 11, such that the air inlet 111 is selectively connected to the first air outlet 112 or to the first air outlet 112 and the second air outlet 113, thereby achieving switching of the first pressure control pipeline 21 and the second pressure control pipeline 31. In actual applications, the switching device 1 may be connected to the lower computer of the semiconductor processing device, and the lower computer may control the switching device 1 when performing different process steps. The above design makes the structure of the embodiments of the present disclosure simple and stable, thereby substantially improving the safety and stability of the embodiments of the present disclosure.

It should be noted that the embodiments of the present disclosure do not limit the structure of the switching device 1. For example, the switching device 1 may also use other reversing valves that satisfy the pressure requirements. Thus, the embodiments of the present disclosure are not limited thereto, and technicians in this field may adjust the configuration according to actual conditions.

In some embodiments, as shown in FIG. 1 and FIG. 2, the main body 11 includes a gas channel 114 and a sliding channel 115. One end of the gas channel 114 is the first gas outlet 112, and the other end is connected to one end of the sliding channel 115. The gas inlet 111 is connected to the gas channel 114. The second gas outlet 113 is connected to the sliding channel 115. The piston 12 includes a sliding portion 121. The sliding portion 121 is slidably arranged in the sliding channel 115. One of one end surface of the sliding portion 121 facing toward the gas channel 114 and an end surface of the sliding channel 115 facing toward the sliding portion 121 includes a first seal 141. The sliding portion 121 may slide to a position where it is sealed and connected to an end surface of the sliding channel 115 through the first seal 141 to disconnect the gas channel 114 and the sliding channel 115. In practical applications, the first seal 141 may also be arranged on the end surface of the sliding channel 115 facing toward the sliding portion 121.

As shown in FIG. 1 and FIG. 2, an axial direction of the main body 11 extends in a horizontal direction. The gas channel 114 and the sliding channel 115 both extend in the horizontal direction. A left end of the gas channel 114 is the first gas outlet 112, and a right end of the gas channel 114 is connected to the sliding channel 115. An inner diameter of the sliding channel 115 may be larger than an inner diameter of the gas channel 114. The gas inlet 111 may extend in a vertical direction, and may be arranged at the top of the gas channel 114. The second gas outlet 113 may be arranged in the vertical direction to be connected to the sliding channel 115. The second gas outlet 113 may be arranged at the bottom of the sliding channel 115. The piston 12 may include the sliding portion 121. The sliding portion 121 is slidably arranged in the sliding channel 115. The end surface of the sliding portion 121 facing toward the gas channel 114 includes the first seal 141. The first seal 141 is, for example, an annular structure made of a flexible material. A receiving groove for receiving the first seal 141 may be opened on the end surface of the sliding portion 121. In practical applications, the sliding portion 121 may move to the left to press the first seal 141 against the left end surface of the sliding channel 115 to disconnect the gas channel 114 and the sliding channel 115. The air inlet 111 is connected to the first air outlet 112. Alternatively, the sliding portion 121 may move to the right, and the gas channel 114 and the sliding channel 115 are connected, such that the air inlet 111 can be connected to the first air outlet 112 and the second air outlet 113 at the same time. The above design substantially saves the space occupied by the embodiments of the present disclosure due to the reasonable structural design, and may also substantially improve the stability and reduce the failure rate due to the simple structure.

It should be noted that the embodiments of the present disclosure do not limit the positions of the air inlet 111 and the second air outlet 113. For example, the air inlet 111 may also be arranged at the bottom of the gas channel 114, and the second air outlet 113 may also be arranged at the bottom of the sliding channel 115. Thus, the embodiments of the present disclosure are not limited thereto, and those skilled in the art may adjust the configuration according to actual conditions.

In some embodiments, as shown in FIG. 1 and FIG. 2, the switching device 1 further includes an end cover 13 arranged on the main body 11. The end cover 13 is located at the other end of the sliding channel 115 facing away from the gas channel 114. The end cover 13 is sealed and connected to the main body 11 through a second seal 142 to seal the sliding channel 115. A sliding hole 131 is provided on the end cover 13. The piston 12 further includes a sliding rod 122 integrally arranged with the sliding portion 121. The sliding rod 122 is penetrated in the sliding hole 131, and slides with the sliding hole 131. A third seal 143 is provided on one of an inner peripheral wall of the sliding hole 131 and an outer peripheral wall of the sliding rod 122. The inner peripheral wall of the sliding hole 131 and the outer peripheral wall of the sliding rod 122 are sealed by the third seal 143.

As shown in FIG. 1 and FIG. 2, the end cover 13 adopts a plate-shaped structure made of metallic material. The end cover 13 may be arranged on a right side of the main body 11 to cover the main body 11 to close the sliding channel 115. The second seal 142 may be provided between the end cover 13 and the main body 11. The second seal 142 may be, for example, an annular structure made of a flexible material. The receiving groove for receiving the second seal 142 may be provided on the end cover 13. The end cover 13 may be connected to the main body 11 through a fastener. The second seal 142 may be pressed into the receiving groove to seal the sliding channel 115, such that the gas channel 114 and the sliding channel 115 in the main body 11 are isolated from the outside. The sliding rod 122 may be integrally formed on the right side of the sliding portion 121, and may slidably penetrate the sliding hole 131 on the end cover 13. Further, the receiving groove and the third seal 143 are provided on the inner wall of the sliding hole 131 to achieve a sealed sliding configuration between the sliding rod 122 and the sliding hole 131, thereby further improving sealing effect of the switching device 1.

It should be noted that the embodiments of the present disclosure do not limit the sealing method between the end cover 13, the main body 11, and the sliding rod 122. For example, the end cover 13 may be sealed with the main body 11 by threading, and the sliding rod 122 may be sealed with the end cover 13 by using a shaft seal. Thus, the embodiments of the present disclosure are not limited thereto, and those skilled in the art may adjust the configuration according to actual conditions.

In some embodiments, as shown in FIG. 1 and FIG. 2, the switching device 1 further includes a driving member 15 arranged on a side of the end cover 13 facing away from the main body 11. The driving member 15 is connected to the sliding rod 122, and is used to drive the sliding portion 121 to reciprocate through the sliding rod 122. For example, the driving member 15 may be a telescopic cylinder. A telescopic rod of the telescopic cylinder may be directly used as the sliding rod 122, or may be connected to the sliding rod 122 to drive the sliding rod 122 to reciprocate. The above design not only reduces the operation and maintenance costs, but also improves the accuracy of pressure control, thereby improving the switching efficiency of the exhaust system.

In some embodiments, as shown in FIG. 1 and FIG. 2, the second pressure control mechanism 3 includes a condensation pipeline component 33. One end of the condensation pipeline component 33 is connected to the second gas outlet 113, and the other end is connected to the second pressure control pipeline 31. The condensation pipeline component 33 is used to condense and recover water vapor in the discharged gases. For example, the second pressure control mechanism 3 is used to control the pressure in the process chamber 100 at the second pressure. When the process chamber 100 is discharged at the second pressure, the discharged gases contain high-temperature water vapor. The condensation pipeline component 33 is used to condense and recover the water vapor in the discharged gases to avoid corrosion to the second pressure control pipeline 31 and the factory exhaust pipeline. After the condensation pipeline component 33 dehumidifies the discharged gases, the discharged gases are discharged to the factory exhaust pipeline through the second pressure control pipeline 31. The above design substantially reduces the failure rate of the embodiments of the present disclosure and extends the service life.

In some embodiments, as shown in FIG. 1 and FIG. 2, the condensation pipeline component 33 includes a bellows 331, a damping tube 332, a condenser 333, a water-gas separator 334, and a water reservoir 335. Two ends of the bellows 331 are respectively connected to the second air outlet 113 and one end of the damping tube 332. The other end of the damping tube 332 is connected to an inlet of the water-gas separator 334. The condenser 333 is covered outside the damping tube 332. The second pressure control pipeline 31 is connected to an outlet of the water-gas separator 334. The water reservoir 335 is connected to a water outlet of the water-gas separator 334. For example, the bellows 331 may be made of metallic material. Due to elasticity of the bellows 331, it may tolerate installation deviation of various components, thereby improving the stability of the embodiments of the present disclosure. A bottom end of the bellows 331 is connected to the damping tube 332 through a straight joint. The condenser 333 is wrapped around an outer periphery of the damping tube 332. Because the damping tube 332 prevents the gases from flowing too fast, the condenser 333 may dehumidify the gases, thereby improving dehumidification efficiency. A top end of the water-gas separator 334 includes an inlet. A bottom end of the damping tube 332 is connected to the inlet of the water-gas separator 334. The other end of the water-gas separator 334 includes an outlet connected to the second pressure control pipeline 31 to discharge the gases after water vapor separation through the second pressure control pipeline 31 to the factory exhaust pipeline. The water outlet is arranged on a side of the bottom of the water-gas separator 334 adjacent to the outlet. The water reservoir 335 is connected to the water outlet of the water-gas separator 334 to recover and store water separated from the gases. The above design allows the embodiments of the present disclosure to achieve water vapor separation with a relatively simple structure, thereby substantially reducing the operation and maintenance costs.

In some embodiments, as shown in FIG. 1 and FIG. 2, the second pressure control mechanism 3 further includes a pressure detection tube 34. One end of the pressure detection tube 34 is connected to the water-gas separator 334, and the other end is connected to the second controller 32, for detecting the pressure signal in the process chamber 100. The second controller 32 is used to control the pressure in the process chamber 100 according to the pressure signal. For example, one end of the pressure detection tube 34 is connected to the water-gas separator 334, and the other end is connected to the second controller 32. When the process chamber 100 is vented using the second pressure control pipeline 31, the pressure detection tube 34 may detect a pressure in the water-gas separator 334 as a proxy for the pressure in the process chamber 100, and may directly send the pressure signal to the second controller 32, to provide a basis for the second controller 32 to control the pressure in the process chamber 100. The above design not only further automates of the embodiments of the present disclosure, but also simplifies the structure of the embodiments of the present disclosure, thereby reducing the efficiency of disassembly and maintenance.

In some embodiments, as shown in FIG. 1 and FIG. 2, the first pressure is 50 Torr. The second pressure is greater than or equal to 650 Torr and smaller than or equal to 760 Torr. In some embodiments, the second pressure is greater than or equal to 758 Torr and smaller than or equal to 760 Torr. For example, the first pressure control pipeline 21 may maintain the pressure in the process chamber 100 at 50 Torr, and the second pressure control pipeline 31 may maintain the pressure in the process chamber 100 at 650 Torr, such that the process chamber 100 can perform the process in the low pressure mode and the micro-low pressure mode. Similarly, the first pressure control pipeline 21 may maintain the pressure in the process chamber 100 at 50 Torr, and the second pressure control pipeline 31 may maintain the pressure in the process chamber 100 at greater than or equal to 758 Torr and less than or equal to 760 Torr, such that the process chamber 100 can perform the process in the low pressure mode and the normal pressure mode. The above design substantially expands the scope of application of the process chamber 100.

To further illustrate the beneficial effects of the embodiments of the present disclosure, the embodiments of the present disclosure will be described below in conjunction with the accompanying drawings. As shown in FIG. 1 and FIG. 2, when the process chamber 100 performs the process at the first pressure, the piston 12 of the switching device 1 slides to the left to close the second gas outlet 113 and to connect the gas inlet 111 with the first gas outlet 112. At this time, the first controller 22 controls the first pressure control pipeline 21 to discharge to control the pressure in the process chamber 100, and at the same time starts the exhaust device 25. In this process, the first detection component 231 is used to detect the pressure in the process chamber 100, and the second detection component 232 is closed at the same time to avoid damage to the second detection component 232 due to the high pressure in the process chamber 100. When the first detection component 231 detects that the pressure in the process chamber 100 is around 50 Torr, the second detection component 232 may be controlled to accurately measure the pressure in the process chamber 100, and the pressure signal is sent to the first controller 22 for automatic pressure control to ensure that the pressure in the process chamber 100 is accurately controlled at 50 Torr.

When the process chamber 100 performs the process at the second pressure, nitrogen may be injected into the process chamber 100 to increase the pressure in the process chamber 100. To prevent the second detection component 232 from being damaged due to out-of-range, the second detection component 232 may be closed. The first detection component 231 is used to detect the pressure in the process chamber 100. To prevent the second controller 32 from being damaged due to out-of-range caused by pressure fluctuation, the pressure differential detection component 24 is used to compare the pressure in the process chamber 100 and the second pressure control pipeline 31. For example, when the threshold of the pressure difference signal is 0, the first controller 22 is controlled to turn off the first pressure control pipeline 21. The piston 12 of the switching device 1 moves to the right to open the second gas outlet 113. At this time, the process chamber 100 is discharged through the second pressure control pipeline 31. The pressure detection tube 34 may detect the pressure in the second pressure control pipeline 31 as the proxy for the pressure in the process chamber 100, and may send the pressure signal to the second controller 32 for automatic pressure control. Further, because the discharged gases contain high-temperature water vapor, when the water vapor passes through the damping tube 332 and the condenser 333, the high-temperature water vapor is condensed into liquid water, and the water-gas separator 334 guides the liquid water into the water reservoir 335. The remaining gases are discharged from the second pressure control pipeline 31 to the factory exhaust pipeline.

Similarly, the present disclosure also provides a semiconductor processing device. The semiconductor processing device includes a process chamber and the exhaust system provided by the embodiments of the present disclosure.

The embodiments of the present disclosure at least provide the following beneficial effects. Two pressure control mechanisms including the first pressure control mechanism and the second pressure control mechanism are provided. The first pressure control mechanism and the second pressure control mechanism are selectively switched through the switching device to discharge and control the process chamber, such that the process chamber can be maintained at the first pressure or the second pressure. Thus, the process chamber is controlled to maintain at one of the two pressures, such as the normal pressure (absolute pressure 758-760 Torr) and the low pressure (absolute pressure 50 Torr). The embodiments of the present disclosure not only substantially expand the scope of application, but also substantially improves the process rate because the two pressure control mechanisms can be quickly switched by the switching device 1.

It should be understood that the above embodiments are merely exemplary embodiments for illustrating the principles of the present disclosure. The present disclosure is not limited thereto. For those with ordinary skills in the art, various modifications and improvements can be made without departing from the spirit and essence of the present disclosure, and these modifications and improvements are also regarded as within the scope of the present disclosure.

In the description of the present disclosure, it should be understood that orientation or positional relationship indicated by terms “center”, “upper”, “lower”, “front”, “back”, “left”, “right”, “vertical”, “horizontal”, “top”, “bottom”, “inside”, “outside”, etc. is based on the orientation or positional relationship shown in the drawings, and is only for the convenience of describing the present disclosure and simplifying the description, rather than indicating or implying that the device or components referred to must have a specific orientation, be constructed and operated in a specific orientation, and therefore cannot be understood as limiting the present disclosure.

The terms “first” and “second” are only used for descriptive purposes, and should not be understood as indicating or implying relative importance or implicitly indicating the number of technical features indicated. Therefore, the features defined as “first” and “second” may explicitly or implicitly include one or more of the features. In the description of the present disclosure, unless otherwise specified, “multiple” means two or more.

In the description of the present disclosure, it should be noted that, unless otherwise clearly specified and limited, the terms “installed”, “attached”, and “connected” should be understood in a broad sense. For example, the connection may be a fixed connection, a detachable connection, or an integral connection. The connection may be directly connected, or indirectly connected through an intermediate medium, or it may be an internal connection between two components. For those with ordinary skills in the art, the meanings of the above terms in the present disclosure can be understood according to specific circumstances.

The above is only a partial implementation of the present disclosure. It should be pointed out that for those with ordinary skills in the art, improvements and modifications can be made without departing from the principles of the present disclosure, and these improvements and modifications should also be regarded as within the scope of the present disclosure.

1. An exhaust system connected to a process chamber in a semiconductor processing device to discharge gases and control a pressure in the process chamber, comprising:
a switching device;
a first pressure control mechanism; and
a second pressure control mechanism;
wherein:
the switching device is connected to the process chamber, and is connected to the first pressure control mechanism and the second pressure control mechanism for switching between the first pressure control mechanism and the second pressure control mechanism to discharge the gases and control the pressure in the process chamber;
the first pressure control mechanism includes a first pressure control pipeline and a first controller, and the first pressure control pipeline is connected to the switching device and is used to discharge the gases in the process chamber; the first controller is disposed at the first pressure control pipeline to control the process chamber to maintain a first pressure when the first pressure control pipeline discharges the gases; and
the second pressure control mechanism includes a second pressure control pipeline and a second controller, and the second pressure control pipeline is connected to the switching device and is used to discharge the gases in the process chamber; the second controller is disposed at the second pressure control pipeline to control the process chamber to maintain a second pressure when the second pressure control pipeline discharges the gases; and the second pressure is greater than the first pressure.

2. The exhaust system according to claim 1, wherein:
the first pressure control mechanism further includes an exhaust device, the exhaust device is connected to the first pressure control pipeline, and the first controller is used to control the exhaust device to discharge the gases in the process chamber.

3. The exhaust system according to claim 2, wherein:
the first pressure control pipeline includes a first exhaust pipe and a variable diameter exhaust pipe, one end of the first exhaust pipe is connected to the switching device, and the other end of the first exhaust pipe is connected to one end of the variable diameter exhaust pipe;
the other end of the variable diameter exhaust pipe is connected to the exhaust device; and
the first controller is arranged at one of the first exhaust pipe and the variable diameter exhaust pipe, or at a connection between the first exhaust pipe and the variable diameter exhaust pipe.

4. The exhaust system according to claim 3, wherein:
the first pressure control mechanism further includes a detection component, which is disposed at the first exhaust pipe and is used to detect a pressure signal in the first exhaust pipe, and the first controller is used to control the pressure in the process chamber according to the pressure signal.

5. The exhaust system according to claim 4, wherein:
the detection component includes a first detection component and a second detection component, the first detection component and the second detection component are arranged at the first exhaust pipe, the second detection component is located on a side of the first detection component facing away from the switching device, and the first detection component has a detection range greater than a detection range of the second detection component.

6. The exhaust system according to claim 5, wherein:
the first pressure control mechanism further includes a pressure differential detection component, two ends of the pressure differential detection component are respectively connected to the first pressure control pipeline and the second pressure control pipeline, for detecting a pressure difference signal between the two; and
when the pressure difference signal reaches a first threshold, the switching device switches from discharging through the first pressure control pipeline to discharging through the second pressure control pipeline, and the first controller is turned off.

7. The exhaust system according to claim 1, wherein:
the switching device includes a main body and a piston, the main body includes an air inlet, a first air outlet, and a second air outlet, the air inlet is connected to an exhaust port of the process chamber, the first air outlet is connected to the first pressure control pipeline, and the second air outlet is connected to the second pressure control pipeline; and
at least a portion of the piston is slidably arranged in the main body, the piston slides back and forth in the main body, and is used to selectively connect the air inlet with the first air outlet or with the first air outlet and the second air outlet.

8. The exhaust system according to claim 7, wherein:
the main body includes a gas channel and a sliding channel, one end of the gas channel is the first gas outlet, the other end of the gas channel is connected to one end of the sliding channel, and the gas inlet is connected to the gas channel; and
the second gas outlet is connected to the sliding channel, the piston includes a sliding portion, the sliding portion is slidably arranged in the sliding channel, and one of an end surface of the sliding portion facing toward the gas channel and an end surface of the sliding channel facing toward the sliding portion includes a first sealing member, and the sliding portion slides to a position where it is sealed and connected to an end surface of the sliding channel through the first sealing member to disconnect the gas channel and the sliding channel.

9. The exhaust system according to claim 8, wherein:
the switching device further includes an end cover arranged on the main body, the end cover is located at the other end of the sliding channel facing away from the gas channel, the end cover is sealed and connected to the main body through a second seal to seal the sliding channel; and
a sliding hole is provided on the end cover, the piston further includes a sliding rod integrally arranged with the sliding portion, the sliding rod is penetrated in the sliding hole and slides with the sliding hole, a third seal is provided on one of an inner peripheral wall of the sliding hole and an outer peripheral wall of the sliding rod, and the inner peripheral wall of the sliding hole and the outer peripheral wall of the sliding rod are sealed by the third seal.

10. The exhaust system according to claim 9, wherein:
the switching device further includes a driving member arranged on a side of the end cover facing away from the main body, and the driving member is connected to the sliding rod, and is used to drive the sliding portion to reciprocate through the sliding rod.

11. The exhaust system according to claim 7, wherein:
the second pressure control mechanism includes a condensation pipeline component, one end of the condensation pipeline component is connected to the second gas outlet, the other end is connected to the second pressure control pipeline, and the condensation pipeline component is used to condense and recover water vapor in the discharged gases.

12. The exhaust system according to claim 11, wherein:
the condensation pipeline component includes a bellows, a damping tube, a condenser, a water-gas separator, and a water reservoir, two ends of the bellows are respectively connected to the second air outlet and one end of the damping tube, the other end of the damping tube is connected to an inlet of the water-gas separator, the condenser is covered outside the damping tube, the second pressure control pipeline is connected to an outlet of the water-gas separator, and the water reservoir is connected to a water outlet of the water-gas separator.

13. The exhaust system according to claim 12, wherein:
the second pressure control mechanism further includes a pressure detection tube, one end of the pressure detection tube is connected to the water-gas separator, the other end is connected to the second controller for detecting the pressure signal in the process chamber, and the second controller is used to control the pressure in the process chamber according to the pressure signal.

14. A semiconductor processing device, comprising a process chamber and an exhaust system connected to the process chamber in a semiconductor processing device to discharge gases and control a pressure in the process chamber, wherein the exhaust system comprises:
a switching device;
a first pressure control mechanism; and
a second pressure control mechanism;
wherein:
the switching device is connected to the process chamber, and is connected to the first pressure control mechanism and the second pressure control mechanism for switching between the first pressure control mechanism and the second pressure control mechanism to discharge the gases and control the pressure in the process chamber;
the first pressure control mechanism includes a first pressure control pipeline and a first controller, and the first pressure control pipeline is connected to the switching device and is used to discharge the gases in the process chamber; the first controller is disposed at the first pressure control pipeline to control the process chamber to maintain a first pressure when the first pressure control pipeline discharges the gases; and
the second pressure control mechanism includes a second pressure control pipeline and a second controller, and the second pressure control pipeline is connected to the switching device and is used to discharge the gases in the process chamber; the second controller is disposed at the second pressure control pipeline to control the process chamber to maintain a second pressure when the second pressure control pipeline discharges the gases; and the second pressure is greater than the first pressure.

15. The semiconductor processing device according to claim 14, wherein:
the first pressure control mechanism further includes an exhaust device, the exhaust device is connected to the first pressure control pipeline, and the first controller is used to control the exhaust device to discharge the gases in the process chamber.

16. The semiconductor processing device according to claim 15, wherein:
the first pressure control pipeline includes a first exhaust pipe and a variable diameter exhaust pipe, one end of the first exhaust pipe is connected to the switching device, and the other end of the first exhaust pipe is connected to one end of the variable diameter exhaust pipe;
the other end of the variable diameter exhaust pipe is connected to the exhaust device; and
the first controller is arranged at one of the first exhaust pipe and the variable diameter exhaust pipe, or at a connection between the first exhaust pipe and the variable diameter exhaust pipe.

17. The semiconductor processing device according to claim 16, wherein:
the first pressure control mechanism further includes a detection component, which is disposed at the first exhaust pipe and is used to detect a pressure signal in the first exhaust pipe, and the first controller is used to control the pressure in the process chamber according to the pressure signal.

18. The semiconductor processing device according to claim 17, wherein:
the detection component includes a first detection component and a second detection component, the first detection component and the second detection component are arranged at the first exhaust pipe, the second detection component is located on a side of the first detection component facing away from the switching device, and the first detection component has a detection range greater than a detection range of the second detection component.

19. The semiconductor processing device according to claim 18, wherein:
the first pressure control mechanism further includes a pressure differential detection component, two ends of the pressure differential detection component are respectively connected to the first pressure control pipeline and the second pressure control pipeline, for detecting a pressure difference signal between the two; and
when the pressure difference signal reaches a first threshold, the switching device switches from discharging through the first pressure control pipeline to discharging through the second pressure control pipeline, and the first controller is turned off.

20. The semiconductor processing device according to claim 14, wherein:
the switching device includes a main body and a piston, the main body includes an air inlet, a first air outlet, and a second air outlet, the air inlet is connected to an exhaust port of the process chamber, the first air outlet is connected to the first pressure control pipeline, and the second air outlet is connected to the second pressure control pipeline; and
at least a portion of the piston is slidably arranged in the main body, the piston slides back and forth in the main body, and is used to selectively connect the air inlet with the first air outlet or with the first air outlet and the second air outlet.
